(19) United States
(12) Patent Application Publication
(10) Pub. No.: US 2026/0331171 A1
(43) Pub. Date: Oct. 22, 2026

(54) MEMORY DEVICES AND METHODS OF MANUFACTURING THEREOF

(71) Applicant: Taiwan Semiconductor Manufacturing Company, Ltd., Hsinchu (TW)

(72) Inventors: Yorinobu Fujino, New Taipei City (TW); Yoshisato Yokoyama, Hsinchu (TW)

(73) Assignee: Taiwan Semiconductor Manufacturing Company, Ltd., Hsinchu (TW)

(21) Appl. No.: 19/180,896

(22) Filed: Apr. 16, 2025

(51) Int. Cl. G11C 13/00; H10B 63/00

(52) U.S. Cl. CPC G11C 13/0028; H10B 63/80

(57) ABSTRACT

A circuit includes a plurality of first memory cells physically disposed in a first region on a first side of a substrate, a driver circuit operatively coupled to the plurality of first memory cells and physically disposed in a second region on the first side of the substrate, and a switch circuit configured to selectively couple a supply voltage to the driver circuit as an operational voltage, and physically disposed on the first side of the substrate. The operational voltage is carried by a first interconnect structure formed on the first side, and at least one of a first interconnect layer and a second interconnect layer formed on a second, opposite side of the substrate.

### BACKGROUND

The semiconductor integrated circuit (IC) industry has experienced exponential growth. As ICs continue to scale down, more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device (or circuit), in accordance with some embodiments.

FIG. 2 illustrates a circuit diagram of an example memory circuit, in accordance with some embodiments.

FIG. 3 illustrates a circuit diagram of an example memory circuit, in accordance with some embodiments.

FIG. 4A illustrates a circuit diagram of an example memory circuit, in accordance with some embodiments.

FIG. 4B illustrates a cross-sectional view of an example memory circuit, in accordance with some embodiments.

FIG. 5 illustrates a circuit diagram of an example memory circuit, in accordance with some embodiments.

FIG. 6 illustrates a circuit diagram of an example memory circuit, in accordance with some embodiments.

FIG. 7 illustrates a circuit diagram of an example memory circuit, in accordance with some embodiments.

FIG. 8 illustrates a flow chart of an example method for operating a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, as fabrication technology advances, the increasing complexity of integrated circuits has led to significant challenges related to IR-drop and signal integrity. These issues arise due mainly to the shortage of metal tracks, which limits the capacity of power delivery networks to effectively distribute power and maintain stable voltage levels. As a result, the reliability and performance of circuits are adversely affected, particularly as designs push for higher densities and faster operating speeds. Therefore, there is a need for addressing these issues and overcoming the limitations of power distribution techniques.

The present disclosure provides techniques for addressing the abovementioned challenges. According to the present disclosure, in some embodiments, a circuit includes a plurality of memory cells physically disposed in a first region on a first side of a substrate, a driver circuit operatively coupled to the plurality of first memory cells and physically disposed in a second region on the first side of the substrate, and a switch circuit configured to selectively couple a supply voltage to the driver circuit as an operational voltage, and physically disposed on the first side of the substrate. The operational voltage can be carried through a first interconnect structure formed on a first side of the substrate, and at least one of a first interconnect layer (or a second interconnect structure) and a second interconnect layer (or a third interconnect structure) formed on a second, opposite side of the substrate. The techniques disclosed herein provide significant advantages for circuits utilizing virtual power lines, which can be wired through the front side (F/S) and/or backside (B/S). By reducing the effective resistance of connections between power headers and circuits, it effectively mitigates IR-drop and electromigration (EM) issues, contributing to improved power integrity. Additionally, the techniques enable a reduction in chip area by allowing for the shrinkage of power header size.

The techniques disclosed herein can be compatible with various transistor structures, including but not limited to, Planar, Fin Field-Effect Transistor (FinFET), and Gate-All-Around (GAA), as well as back-end processes. Furthermore, it can be implemented in diverse circuit types, including those with virtual power integrated within the circuit. Particularly, the techniques can be suited for memory macros with power switches inside the macro, especially when fabricated with a backside power delivery network (BSPDN). The enhancement of virtual powerlines through low effective resistance and high decoupling capacitance ensures its applicability across a wide range of circuits, significantly improving performance and scalability.

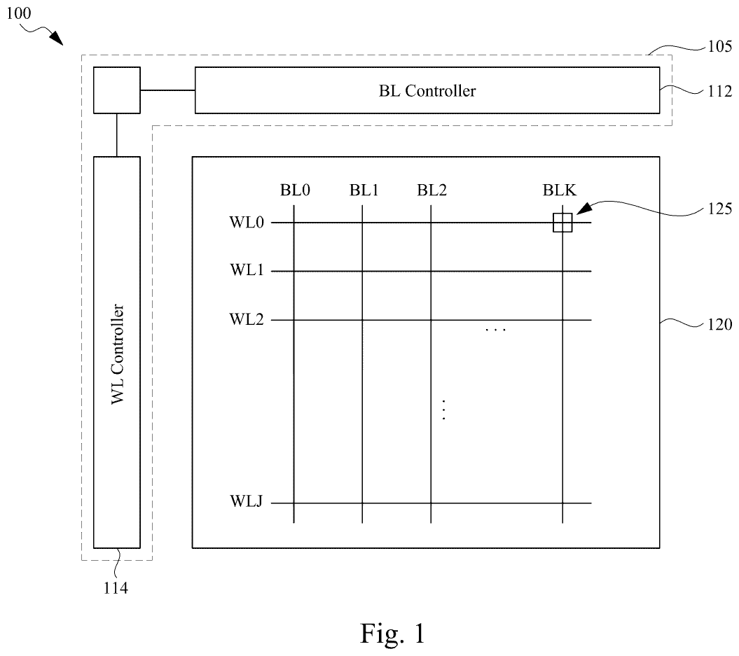

FIG. 1 illustrates a block diagram of an example memory device (or circuit) 100, in accordance with some embodiments. The memory circuit 100 includes a memory controller 105 and a memory array 120. In one aspect, the memory array 120 includes a plurality of storage circuits or memory cells 125. The memory array 120 further includes word lines WL₀, WL₁ . . . WL_{J}, each extending in a direction (e.g., the X-direction) and bit lines BL₀, BL₁ . . . BL_{K}, each extending in another direction (e.g., the Y-direction). The word lines WLs and the bit lines BLs may each be a conductive metal or conductive rail. In some embodiments, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the direction (e.g., the Y-direction). The bit lines BL, BLB may receive and/or provide differential signals.

Each memory cell 125 may include a volatile memory cell, a non-volatile memory cell, or a combination of them. In some embodiments, the memory cells 125 each include a resistive random access memory (RRAM) cell. In some embodiments, each memory cell 125 is embodied as a static random access memory (SRAM) cell, etc. However, it should be appreciated that the memory cell 125 can be implemented as any of various other non-volatile memory cells such as, for example, a magnetoresistive random access memory (MRAM) cell, a phase-change random access memory (PCRAM) cell, an eFuse, an anti-fuse, etc., while remaining within the scope of the present disclosure. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line (BL) controller 112, a word line (WL) controller 114, etc. The BL controller 112 and the WL controller 114 may be embodied as logic circuits, analog circuits, or a combination of them. In one configuration, the WL controller 114 can be a circuit that provides a voltage or current through one or more word lines WLs of the memory array 120. The BL controller 112 can be a circuit that provides or senses a voltage or current through one or more bit lines BLs of the memory array 120. The BL controller 112 may be coupled to bit lines BLs of the memory array 120, and the WL controller 114 may be coupled to word lines WLs of the memory array 120.

In some embodiments, the memory circuit 100 includes a plurality of first memory cells (e.g., included in the memory array 120) physically disposed in a first region on a first side of a substrate. In some embodiments, the memory circuit 100 includes a driver circuit (e.g., included in the memory controller 105) operatively coupled to the plurality of first memory cells and physically disposed in a second region on the first side of the substrate. In some embodiments, the memory circuit 100 includes a switch circuit (e.g., included in the memory controller 105) configured to selectively couple a supply voltage to the driver circuit as an operational voltage, and physically disposed on the first side of the substrate. In some embodiments, the operational voltage can be carried through a first interconnect structure, and at least one of a first interconnect layer (or a second interconnect structure) and a second interconnect layer (or a third interconnect structure). In some embodiments, the first interconnect structure may be formed on the first side of the substrate. The first interconnect layer (or the second interconnect structure) may be formed on a second, opposite side of the substrate. The second interconnect layer (or the third interconnect structure) may be formed on the second side of the substrate.

With the foregoing in mind, the figures and description below illustrate various examples of the techniques for memory circuits (e.g., the memory circuit 100). The figures and description below are non-limiting examples and can be implemented as any of various other configurations while remaining within the scope of the present disclosure. Other embodiments can be used in addition or instead. Details that can be apparent to a person of ordinary skill in the art may be omitted. Some embodiments can be practiced with additional components or steps and/or without all of the components or steps that are described.

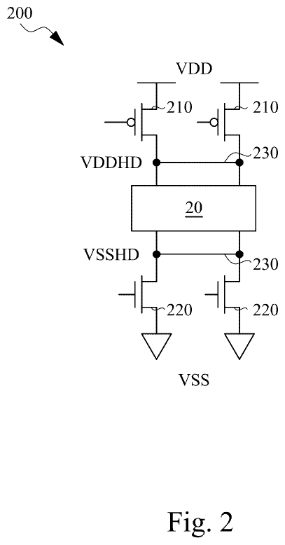

FIG. 2 illustrates a circuit diagram of an example memory circuit 200, in accordance with some embodiments. In some embodiments, the memory circuit 200 may be substantially similar to or incorporate features of the memory circuit 100. The memory circuit 200 is shown to include a circuit 20, first transistors 210, second transistors 220, interconnect structures 230, etc. It should be appreciated that the memory circuit 200 of FIG. 2 is simplified for illustrative purposes, and thus, can be implemented as any of various other configurations while remaining within the scope of the present disclosure.

In some embodiments, the circuit 20 may be any circuit or circuit component of the memory controller 105. For example, the circuit 20 may be or include, but not limited to, a driver circuit, a WL repeater circuit, etc. In some embodiments, the circuit 20 can be operatively coupled to first memory cells associated with the memory circuit 200. In some embodiments, when the first memory cells are disposed in a first region (e.g., a top portion adjacent to the first transistors 210) on a first side (e.g., front-side, F/S) of a substrate, the circuit 20 can be physically disposed in a second region (e.g., between the first transistors 210 and the second transistors 220) on the first side (e.g., front-side, F/S) of the substrate. In some embodiments, the memory circuit 200 may be include a switch circuit configured to selectively couple a supply voltage to the circuit 20 (e.g., the driver circuit) as an operational voltage. In some embodiments, the switch circuit can be physically disposed on the first side of the substrate. As disclosed herein, in some embodiments, the operational voltage can be carried through a first interconnect structure, and at least one of a first interconnect layer (or a second interconnect structure) and a second interconnect layer (or a third interconnect structure). The first interconnect structure may be formed on the first side of the substrate. The first interconnect layer (or the second interconnect structure) may be formed on a second, opposite side (e.g., back-side, B/S) of the substrate, for example, the interconnect structure 230. The second interconnect layer (or the third interconnect structure) may be formed on the second side of the substrate.

In some embodiments, the memory circuit 20 may include second memory cells physically disposed in a third region (e.g., a bottom portion adjacent to the second transistors 220) on the first side of the substrate. For example, the third region can be placed opposite the second region from the first region. In some embodiments, with the supply voltage equal to VDD, the memory circuit 200 can include one or more p-type transistors. For example, as shown in FIG. 2, the memory circuit 200 can include the first transistors 210 (e.g., p-type transistors). In some embodiments, the first transistors 210 can be coupled to the VDD (e.g., true power) on the first side (e.g., F/S) and/or the second side (e.g., B/S). In some embodiments, with the supply voltage equal to VSS, the memory circuit 200 can include one or more n-type transistors. For example, as shown in FIG. 2, the memory circuit 200 can include the second transistors 220 (e.g., n-type transistors). In some embodiments, the second transistors 220 can be coupled to the VSS (e.g., true power) on the first side (e.g., F/S) and/or the second side (e.g., B/S).

In some embodiments, the memory circuit 200 can include the interconnect structures 230 on the first side (e.g., F/S) and/or the second side (e.g., B/S). That is, while the true powers (e.g., VDD, VSS) can be wired with F/S metals and/or B/S metals, virtual powers (e.g., VDDHD, VSSHD, etc.) can be wired with F/S metals and/or B/S metals. The B/S virtual powers can reduce the effective resistance of connections between the headers and circuits, while mitigating the IR-drop and EM issues of the virtual powers.

With the foregoing in mind, the figures and description below illustrate various examples of the techniques for the B/S virtual powers. The figures and description below are non-limiting examples and can be implemented as any of various other configurations while remaining within the scope of the present disclosure. Other embodiments can be used in addition or instead. Details that can be apparent to a person of ordinary skill in the art may be omitted. Some embodiments can be practiced with additional components or steps and/or without all of the components or steps that are described.

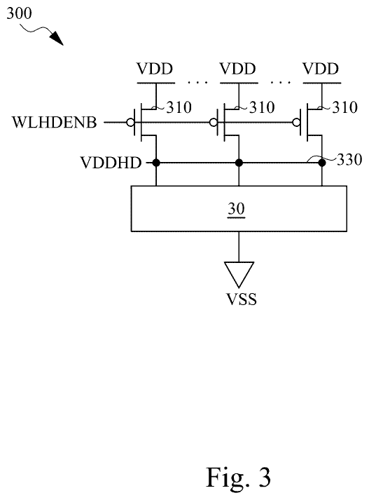

FIG. 3 illustrates a circuit diagram of an example memory circuit 300, in accordance with some embodiments. In some embodiments, the memory circuit 300 may be substantially similar to or incorporate features of the memory circuits 100, 200, etc. The memory circuit 300 is shown to include a circuit 30, first transistors 310, an interconnect structures 330, etc. It should be appreciated that the memory circuit 300 of FIG. 3 is simplified for illustrative purposes, and thus, can be implemented as any of various other configurations while remaining within the scope of the present disclosure.

In some embodiments, the memory circuit 30 may be any circuit or circuit component of the memory controller 105. In some embodiments, the memory circuit 300 may be or include a power header for the WL circuits, and the circuit 30 may be or include a circuit for the WL driver. In some embodiments, the circuit 30 can be operatively coupled to first memory cells associated with the memory circuit 300. In some embodiments, when the first memory cells are disposed in a first region (e.g., a top portion adjacent to the first transistors 310) on a first side (e.g., F/S) of a substrate, the circuit 30 can be physically disposed in a second region (e.g., adjacent to the first transistors 310) on the first side (e.g., F/S) of the substrate. In some embodiments, the memory circuit 300 may be include a switch circuit configured to selectively couple a supply voltage to the circuit 30 as an operational voltage. In some embodiments, the switch circuit can be physically disposed on the first side of the substrate. As disclosed herein, in some embodiments, the operational voltage can be carried through a first interconnect structure, and at least one of a first interconnect layer (or a second interconnect structure) and a second interconnect layer (or a third interconnect structure). The first interconnect structure may be formed on the first side (e.g., F/S) of the substrate. The first interconnect layer (or the second interconnect structure) may be formed on a second, opposite side (e.g., B/S) of the substrate, for example the interconnect structure 330. The second interconnect layer (or the third interconnect structure) may be formed on the second side of the substrate.

In some embodiments, with the supply voltage equal to VDD, the memory circuit 300 can include one or more p-type transistors. For example, as shown in FIG. 3, the memory circuit 300 can include the first transistors 310 (e.g., p-type transistors). In some embodiments, the first transistors 310 can be coupled to the VDD (e.g., true power) on the first side (e.g., F/S) and/or the second side (e.g., B/S). Although not shown, in some embodiments, with the supply voltage equal to VSS, the memory circuit 300 can include one or more n-type transistors. In some embodiments, the memory circuit 300 can include the interconnect structures 330 on the first side (e.g., F/S) and/or the second side (e.g., B/S). That is, while the true powers (e.g., VDD) can be wired with F/S metals and/or B/S metals, the virtual powers (e.g., VDDHD, etc.) can be wired with F/S metals and/or B/S metals. The B/S virtual powers can reduce the effective resistance of connections between the headers and circuits, while mitigating the IR-drop and EM issues of the virtual powers.

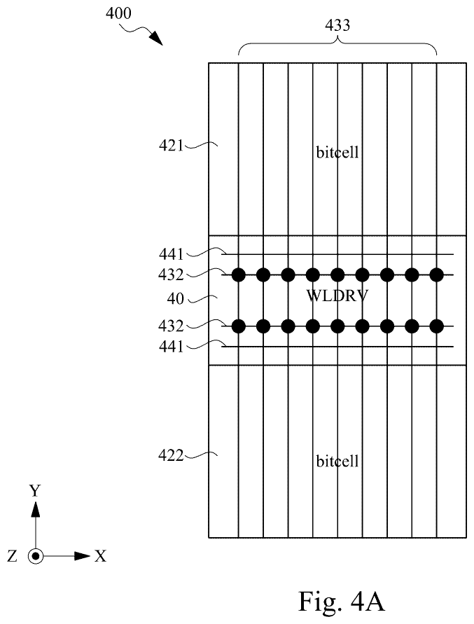

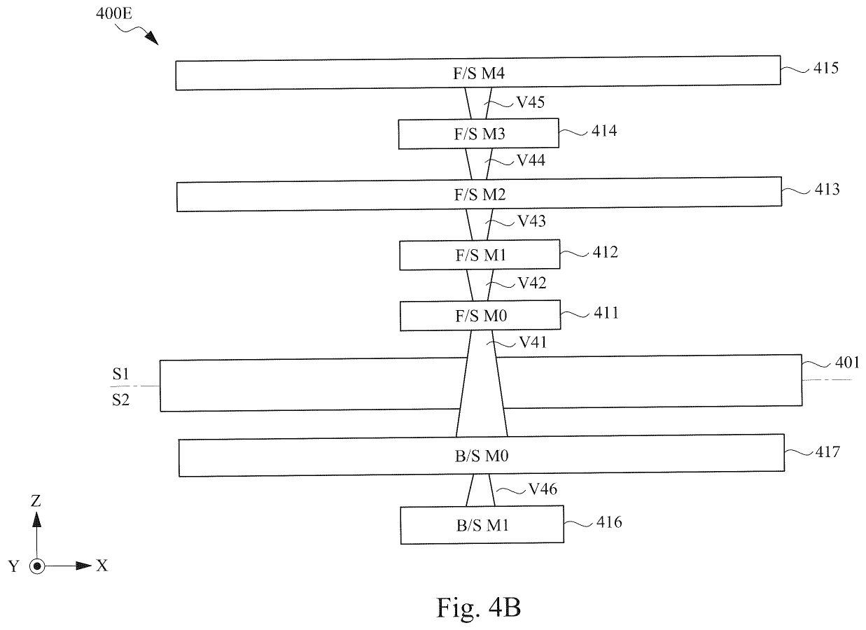

FIG. 4A illustrates a circuit diagram of an example memory circuit 400, in accordance with some embodiments. In some embodiments, the memory circuit 400 may be substantially similar to or incorporate features of the memory circuits 100, 200, 300, etc. The memory circuit 400 is shown to include a driver circuit 40, first memory cells 421, second memory cells 422, first interconnect structures 441, second interconnect structures 432, and third interconnect structures 433, etc. It should be appreciated that the memory circuit 400 of FIG. 4A is simplified for illustrative purposes, and thus, can be implemented as any of various other configurations while remaining within the scope of the present disclosure.

In some embodiments, the memory circuit 400 can include the first memory cells 421 physically disposed in a first region (e.g., a top portion of the memory circuit 400 shown in FIG. 4A) on a first side (e.g., F/S) of a substrate. In some embodiments, the driver circuit 400 can be operatively coupled to the first memory cells 421 and physically disposed in a second region (e.g., between the first memory cells 421 and the second memory cells 422) on the first side of the substrate. In some embodiments, the driver circuit 40 may be or include a WL driver or WL driver circuit (e.g., WLDRV, as shown in FIG. 4A). In some embodiments, the driver circuit 40 can be configured to assert one or more of the first memory cells 421 through a fourth interconnect structure (not shown) formed on the first side of the substrate. In some embodiments, the memory circuit 400 can include the second memory cells 422 physically disposed in a third region (e.g., a bottom portion of the memory circuit 400 shown in FIG. 4A) on the first side of the substrate. In some embodiments, the third region can be placed opposite the second region from the first region.

In some embodiments, the memory circuit 400 can include the first interconnect structures 441 formed on the first side (e.g., F/S) of the substrate. In some embodiments, the memory circuit 400 can include the second interconnect structures 432 formed on a second side of the substrate. In some embodiments, the second side of the substrate maybe an opposite side (e.g., to the first side) of the substrate. For example, the first side is a front side (e.g., F/S) and the second side is a back side (e.g., B/S). In some embodiments, the memory circuit 400 can include the third interconnect structures 433 formed on the second side of the substrate.

The first interconnect structures 441 can be located in any of F/S metallization layers. For example, the first interconnect structures 441 can be located in a third metallization layer (e.g., “M2”) and/or a fifth metallization layer (e.g., “M4”). The second interconnect structures 432 and/or the third interconnect structures 433 can be located in any of B/S metallization layers. In some embodiments, the second interconnect structures 432 can be located in a first B/S metallization layer (e.g., “M0”), a second B/S metallization layer (e.g., “M1”), or any other B/S metallization layers. In some embodiments, the third interconnect structures 433 can be located in the first B/S metallization layer (e.g., “M0”), the second B/S metallization layer (e.g., “M1”), or any other B/S metallization layers. For example, the second interconnect structures 432 can be located in the first metallization layer (e.g., “M0”), while the third interconnect structures 433 can be located in the second metallization layer (e.g., “M1”). The second interconnect structures 432 (e.g., located in the first metallization layer, M0) can reduce the effective resistance, while the third interconnect structures 433 (e.g., located in the second metallization layer, M1) can be used for de-coupling capacitance. In some embodiments, the second interconnect structures 432 can extend in a first lateral direction (e.g., the X-direction, as shown in FIG. 4A). The third interconnect structures 433 can extend in a second lateral direction (e.g., the Y-direction, as shown in FIG. 4A). In some embodiments, the first lateral direction can be perpendicular to the second lateral direction. Example configurations of the first interconnect structures 441, the second interconnect structure 432, the third interconnect structures 433, etc. are discussed in greater detail with respect to FIG. 4B.

In some embodiments, the memory circuit 400 can operate based on the virtual power (e.g., VDDHD), carried through the first interconnect structures 441 and at least one of the second interconnect structures 432 and the third interconnect structures 433. The capacitance of the virtual power can be thereby de-coupled, while further reduction of the IR-drop can be achieved through the de-coupled capacitance.

In some embodiments, the memory circuit 400 can include a switch circuit configured to selectively couple a supply voltage to the driver circuit 40 as an operational voltage. In some embodiments, the switch circuit can be physically disposed on the first side (e.g., F/S) of the substrate. In some embodiments, the operational voltage can be carried through the first interconnect structures 441, and at least one of the second interconnect structures 432 (or a first interconnect layer including the second interconnect structure 432) and the third interconnect structures 433 (or a second interconnect layer including the third interconnect structure 433).

FIG. 4B illustrates a cross-sectional view of an example memory circuit 400E, in accordance with some embodiments. In some embodiments, shown in FIG. 4B is a cross-sectional view of an example of the memory circuit 400 shown in FIG. 4A. The memory circuit 400E may include a substrate 401, a first B/S metallization layer 411, a second B/S metallization layer 412, a third B/S metallization layer 413, a fourth B/S metallization layer 414, a fifth B/S metallization layer 415, a first B/S metallization layer 415 and a second B/S metallization layer 416. It should be appreciated that the memory circuit 400E of FIG. 4E is simplified for illustrative purposes, and thus, can be implemented as any of various other configurations while remaining within the scope of the present disclosure.

A first side S1 of the substrate 401 includes the first B/S metallization layer 411, the second B/S metallization layer 412, the third B/S metallization layer 413, the fourth B/S metallization layer 414, and the fifth B/S metallization layer 415. A second side S2 of the substrate 401 includes the first B/S metallization layer 415 and the second B/S metallization layer 416. The second side S2 may be an opposite side of the first side S1. The first B/S metallization layer 411, the second B/S metallization layer 412, the third B/S metallization layer 413, the fourth B/S metallization layer 414, and the fifth B/S metallization layer 415 may be connected through a plurality of via structures V41 to V45. The first B/S metallization layer 415 and the second B/S metallization layer 416 may be connected through a plurality of via structures V41, V46. As a non-limiting example, each of (i) at least one of the first to fifth F/S metallization layers 411 to 415 and (ii) at least one of the first B/S metallization layer 415 and the second B/S metallization layer 416 may include one or more interconnect structures configured to carry the operational voltage.

In some embodiments, the first interconnect structures 441 of the memory circuit 400 in FIG. 4A may be located in any of first to fifth F/S metallization layers 411 to 415 of the memory circuit 400E. For example, the first interconnect structures 441 may be located in the third F/S metallization layer 413 and/or the fifth metallization layer 415. In some embodiments, the first and second F/S metallization layers 411, 412 may be used for local connections, while the third and fifth F/S metallization layers 413, 415 may be used for global VDDHD connections.

In some embodiments, the second interconnect structures 432 and/or the third interconnect structures 433 of the memory circuit 400 in FIG. 4A may be located in any of the first and second B/S metallization layers 411, 416 of the memory circuit 400E. For example, the second interconnect structures 432 may be located in the first B/S metallization layer 415, the second B/S metallization layer 416, or any other B/S metallization layers. In some embodiments, the third interconnect structures 433 of the memory circuit 400 in FIG. 4A may be located in the first B/S metallization layer 415, the second B/S metallization layer 416, or any other B/S metallization layers. For example, the second interconnect structures 432 may be located in the first B/S metallization layer 415, while the third interconnect structures 433 may be located in the second B/S metallization layer 416. The second interconnect structures 432 (e.g., located in the first B/S metallization layer, MO) can reduce the effective resistance, while the third interconnect structures 433 (e.g., located in the second B/S metallization layer, M1) can be used for de-coupling capacitance. In some embodiments, a higher level F/S metallization layer (e.g., a sixth F/S metallization layer “M5,” a seventh F/S metallization layer “M6,” etc.), although not shown, may be configured to couple VDD/VSS in a memory block level. In some embodiments, a higher level B/S metallization layer (e.g., a third B/S metallization layer “M3,” etc.), although not shown, may be configured to couple VDD/VSS in a memory block level.

In some embodiments, the operational voltage may be carried by a first interconnect structure formed on the first side S1 of the substrate 401 (e.g., any of the first to fifth F/S metallization layers 411 to 415), and at least one of a second interconnect structure formed on the second side S2 of the substrate 401 (e.g., any of the first and second B/S metallization layers 415, 416) and a third interconnect structure formed on the second side S2 of the substrate 401 (e.g., any of the first and second B/S metallization layers 415, 416).

In some embodiments, the first B/S metallization layer 415 and/or the second interconnect structures 432 can extend in a first lateral direction (e.g., the X-direction, as shown in FIG. 4B). The second B/S metallization layer 416 and/or the third interconnect structures 433 can extend in a second lateral direction (e.g., the Y-direction, as shown in FIG. 4B). In some embodiments, the first lateral direction can be perpendicular to the second lateral direction.

Referring to FIG. 3, FIG. 4A, and FIG. 4B, the circuits disclosed herein (e.g., the circuits 100, 200, 300, 400, etc.) can include various circuit components. In some embodiments, the circuits can include a logic component and/or circuit to perform various logic operations to control the virtual power. For example, the circuit 300 can include one or more logic components or gates between the first transistors 310 and the circuit 300. Such logic components or gates can control the virtual power before it is delivered, allowing for power modulation and/or optimization.

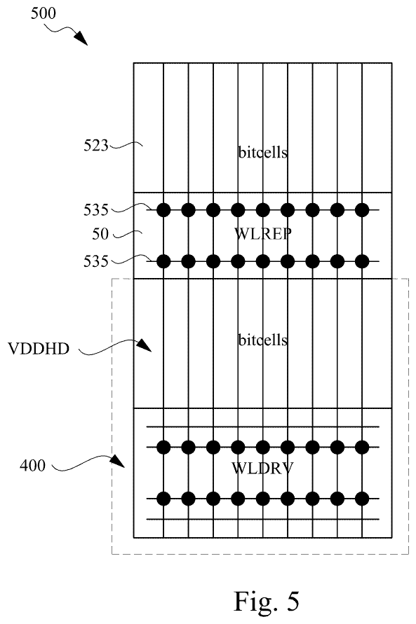

FIG. 5 illustrates a circuit diagram of an example memory circuit 500, in accordance with some embodiments. In some embodiments, the memory circuit 500 may be substantially similar to or incorporate features of the memory circuits 100, 200, 300, 400, etc. For example, the memory circuit 500 may be the memory circuit 400, including at least a portion of the memory circuit 400 as shown, and additionally including a repeater circuit (WLREP) 50 and third memory cells 523. It should be appreciated that the memory circuit 500 of FIG. 5 is simplified for illustrative purposes, and thus, can be implemented as any of various other configurations while remaining within the scope of the present disclosure.

In some embodiments, the circuit 500 includes the repeater circuit 50 operatively coupled to the driver circuit 40 and physically disposed in a fourth region adjacent to the first region. For example, the driver circuit 40 is physically disposed such that the repeater circuit 50 is located opposite to the driver circuit 40 from the first memory cells 421. In some embodiments, the repeater circuit 50 can be physically disposed between the first memory cells 421 and the third memory cells 523. In some embodiments, the circuit 500 includes the third memory cells 523 physically disposed in a fifth region on the first side of the substrate. In some embodiments, as shown in FIG. 5, the fifth region can be placed opposite the first region (e.g., in which the first memory cells 421 are located) from the fourth region (e.g., in which the repeater circuit 50 is located).

In some embodiments, the repeater circuit 50 can be coupled to the driver circuit 40 through the third interconnect structures 433 formed on the second side (e.g., B/S) of the substrate. For example, the third interconnect structures 433 can be formed on the second metallization layer (e.g., “M1”) on the second side (e.g., B/S), which can be configured to operatively couple the repeater circuit 50 with the driver circuit 40. That is, in some embodiments, the third interconnect structures 433 can extend through the repeater circuit 50. In some embodiments, the third interconnect structures 433 can be configured to operatively couple the third memory cells 523 with at least one of the repeater circuit 50, the driver circuit 40, etc. In some embodiments, the third interconnect structures 433 can extend through the third memory cells 523.

In some embodiments, the repeater circuit 50 can include fifth interconnect structures 535. In some embodiments, the fifth interconnect structures 535 can be formed on the second side (e.g., B/S) of the substrate. The fifth interconnect structures 535 can be located in any of B/S metallization layers. In some embodiments, the fifth interconnect structures 535 can be located in a first B/S metallization layer (e.g., “M0”), a second B/S metallization layer (e.g., “M1”), or any other B/S metallization layers.

Although shown as including both the second interconnect structures 441 in the driver circuit 40 and the fifth interconnect structures 535 in the repeater circuit 50, in some embodiments, the memory circuit 500 may include either one of the second interconnect structures 441 and the fifth interconnect structures 535. For example, the memory circuit 500 may include, with omitting the second interconnect structures 441, the fifth interconnect structures 535 in the repeater circuit 50.

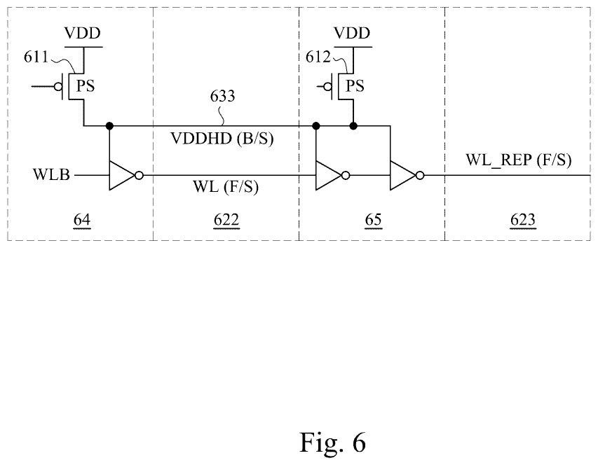

FIG. 6 illustrates a circuit diagram of an example memory circuit 600, in accordance with some embodiments. In some embodiments, the memory circuit 600 may be substantially similar to or incorporate features of the memory circuits 100, 200, 300, 400, 500, etc. For example, the memory circuit 600 may be the memory circuit 500, including a driver circuit 64, a repeater circuit 65, first memory cells 622, third memory cells 623, and a third interconnect structure 633. In some embodiments, the memory circuit 600 includes a first transistor 611 and a second transistor 612. It should be appreciated that the memory circuit 600 of FIG. 6 is simplified for illustrative purposes, and thus, can be implemented as any of various other configurations while remaining within the scope of the present disclosure.

As shown in FIG. 6, in some embodiments, with the supply voltage equal to VDD, the driver circuit 64 of the memory circuit 600 can include one or more p-type transistors. For example, as shown in FIG. 6, the memory circuit 600 can include the first transistor 611 (e.g., p-type). In some embodiments, with the supply voltage equal to VDD, the repeater circuit 65 of the memory circuit 600 can include one or more p-type transistors. For example, as shown in FIG. 6, the memory circuit 600 can include the second transistor 611 (e.g., p-type). In some embodiments, the memory circuit 600 can include the third interconnect structure 633 on the second side (e.g., B/S). In some embodiments, the third interconnect structure 633 can be configured to connect the driver circuit 64 to the repeater circuit 65 with the virtual power VDDHD (e.g., shunting the virtual power of the driver circuit 64 and the repeater circuit 65).

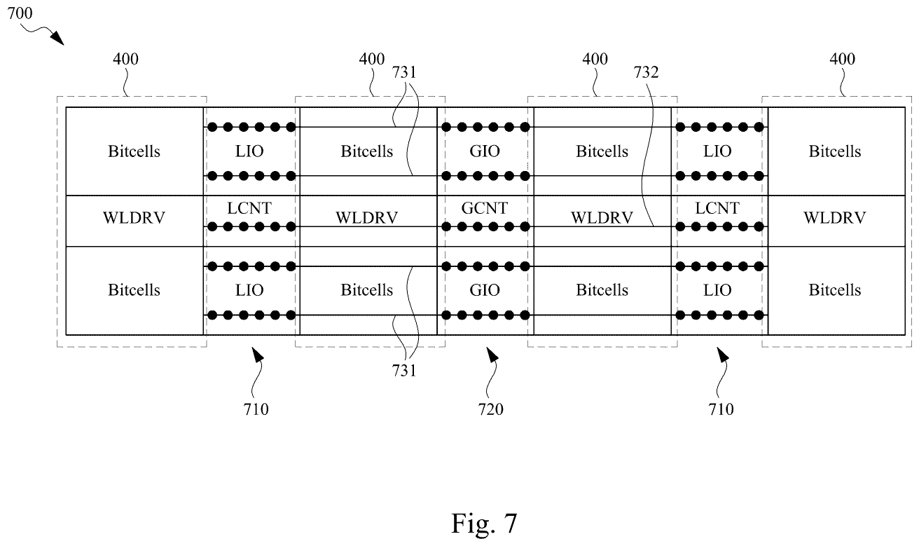

FIG. 7 illustrates a circuit diagram of an example memory circuit 700, in accordance with some embodiments. In some embodiments, the memory circuit 700 may be substantially similar to or incorporate features of the memory circuits 100, 200, 300, 400, 500, 600, etc. For example, the memory circuit 700 may be a circuit including a plurality of the memory circuits 400, operatively coupled to one another, as shown in FIG. 7. The memory circuit 700 is shown to include local I/O circuits 710, a global I/O circuit 720, first interconnect structures 731, a second interconnect structure 732, etc. It should be appreciated that the memory circuit 600 of FIG. 6 is simplified for illustrative purposes, and thus, can be implemented as any of various other configurations while remaining within the scope of the present disclosure.

In some embodiments, the first interconnect structures 731 can be formed on a second side (e.g., B/S) of a substrate. The first interconnect structures 731 can be configured to connect the local I/O (LIO) of the local I/O circuit 710 with the global I/O (GIO) of the global I/O circuit 720, based on virtual powers. In some embodiments, the second interconnect structure 732 can be formed on the second side (e.g., B/S) of the substrate. The second interconnect structure 732 can be configured to connect the local control circuit (LCNT) of the local I/O circuit 710 with the global control circuit (GCNT) of the global I/O circuit 720, based on the virtual powers. For example, the first interconnect structures 731 and/or the second interconnect structure 732 can be configured to connect the local I/O circuit 710 to the global I/O circuit 720 with the virtual power VDDHD (e.g., shunting the virtual power of the local I/O circuit 710 and the global I/O circuit 720). In some embodiments, the first interconnect structures 731 and/or the second interconnect structure 732 can be configured to apply a negative VSS or an overdrive VDD for write-assist operations.

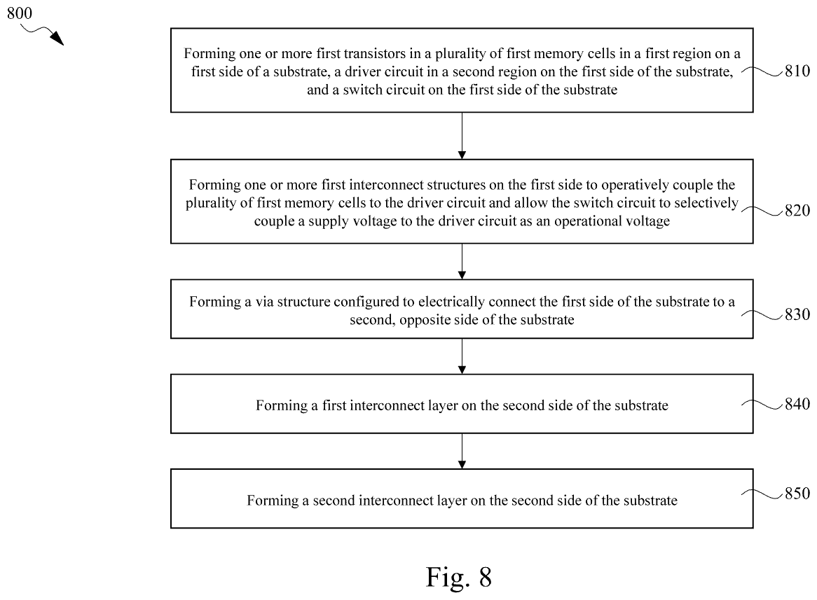

FIG. 8 illustrates a flow chart of an example method 800 for operating a memory circuit, in accordance with some embodiments. In some embodiments, the method 800 can be performed to operate a memory circuit (e.g., the memory circuit 100, etc.), and thus, some of the references used above may be reused in the following discussion of the method 800. It is noted that the method 800 is merely an example and is not intended to limit the present disclosure. Accordingly, it is understood that additional operations may be provided before, during, and after the method 800 of FIG. 8, and that some other operations may only be briefly described herein.

In a brief overview, the method 800 may begin with operation 810 of forming one or more first transistors in a plurality of first memory cells in a first region on a first side of a substrate, a driver circuit in a second region on the first side of the substrate, and a switch circuit on the first side of the substrate. The method 800 may continue to operation 820 of forming one or more first interconnect structures on the first side to operatively couple the plurality of first memory cells to the driver circuit and allow the switch circuit to selectively couple a supply voltage to the driver circuit as an operational voltage. The method 800 may continue to operation 830 of forming a via structure configured to electrically connect the first side of the substrate to a second, opposite side of the substrate. The method 800 may continue to operation 840 of forming a first interconnect layer on the second side of the substrate. The method 800 may continue to operation 850 of forming a second interconnect layer on the second side of the substrate.

At operation 810, the method 800 can include forming one or more first transistors in a plurality of first memory cells (e.g., the first memory cells 421) in a first region on a first side of a substrate (e.g., the first side S1 of the substrate 401 in FIG. 4B), a driver circuit (e.g., the circuit 40) in a second region on the first side of the substrate, and a switch circuit on the first side of the substrate. At operation 820, the method 800 can include forming one or more first interconnect structures (e.g., the first interconnect structures 441, and/or an interconnect structure located in any of the first to fifth F/S metallization layers 411 to 415 of the memory circuit 400E) on the first side to operatively couple the plurality of first memory cells to the driver circuit and allow the switch circuit to selectively couple a supply voltage to the driver circuit as an operational voltage.

In some embodiments, the method 800 can include forming a repeater circuit (e.g., the circuit 50), operatively coupled to the driver circuit, in a fourth region adjacent to the first region. The repeater circuit may be coupled to the driver circuit through a second interconnect layer (e.g., the first or second B/S metallization layers 415, 416 of FIG. 4B) formed on a second side of the substrate (e.g., the second side S2 of the substrate 401 in FIG. 4B). In some embodiments, the method 800 can include forming one or more second transistors in a plurality of second memory cells (e.g., the second memory cells 422) in a third region on the first side of the substrate. The third region may be placed opposite the second region from the first region. In some embodiments, the method 800 can include forming one or more p-type transistors (e.g., the first transistors 210) in the switch circuit to provide the supply voltage equal to VDD. The method 800 can include forming one or more n-type transistors (e.g., the second transistors 220) in the switch circuit to provide the supply voltage equal to VSS.

At operation 830, the method 800 can include forming a via structure (e.g., the via structure V41) configured to electrically connect the first side of the substrate to a second, opposite side of the substrate (e.g., the second side S2 of the substrate 401 in FIG. 4B). At operation 840, the method 800 can include forming a first interconnect layer (e.g., the first B/S metallization layer 415 of FIG. 4B) on the second side of the substrate. At operation 850, the method 800 can include forming a second interconnect layer (e.g., the second B/S metallization layer 416 of FIG. 4B) on the second side of the substrate. In some embodiments, the first interconnect layer may extend in a first lateral direction and the second interconnect layer may extend in a second lateral direction, the first lateral direction being perpendicular to the second lateral direction. The operational voltage can be carried by the first interconnect structure, and at least one of the first interconnect layer and the second interconnect layer.

In one aspect of the present disclosure, a memory circuit is disclosed. The memory circuit includes a plurality of first memory cells physically disposed in a first region on a first side of a substrate, a driver circuit operatively coupled to the plurality of first memory cells and physically disposed in a second region on the first side of the substrate, and a switch circuit configured to selectively couple a supply voltage to the driver circuit as an operational voltage, and physically disposed on the first side of the substrate. The operational voltage is carried by a first interconnect structure formed on the first side, and at least one of a first interconnect layer and a second interconnect layer formed on a second, opposite side of the substrate.

In another aspect of the present disclosure, a memory circuit is disclosed. The memory circuit includes a driver circuit physically disposed in a first region on a first side of a substrate, between a plurality of first memory cells and a plurality of second memory cells, a switch circuit configured to selectively couple a supply voltage to the driver circuit as an operational voltage. An operational voltage is carried through at least a first interconnect structure, a second interconnect structure, and a third interconnect structure. The first interconnect structure is formed on the first side of the substrate, the second interconnect structure formed on a second, opposite side of the substrate, and the third interconnect structure formed on the second side of the substrate.

In yet another aspect of the present disclosure, a method is disclosed. The method includes forming one or more first transistors in a plurality of first memory cells in a first region on a first side of a substrate, a driver circuit in a second region on the first side of the substrate, and a switch circuit on the first side of the substrate, forming one or more first interconnect structures on the first side to operatively couple the plurality of first memory cells to the driver circuit and allow the switch circuit to selectively couple a supply voltage to the driver circuit as an operational voltage, forming a via structure configured to electrically connect the first side of the substrate to a second, opposite side of the substrate, forming a first interconnect layer on the second side of the substrate, and forming a second interconnect layer on the second side of the substrate. The operational voltage is carried by the first interconnect structure, and at least one of the first interconnect layer and the second interconnect layer.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A circuit, comprising:
a plurality of first memory cells physically disposed in a first region on a first side of a substrate;
a driver circuit operatively coupled to the plurality of first memory cells and physically disposed in a second region on the first side of the substrate; and
a switch circuit configured to selectively couple a supply voltage to the driver circuit as an operational voltage, and physically disposed on the first side of the substrate;
wherein the operational voltage is carried by a first interconnect structure formed on the first side, and at least one of a first interconnect layer and a second interconnect layer formed on a second, opposite side of the substrate.

2. The circuit of claim 1, wherein the first interconnect layer extends in a first lateral direction and the second interconnect layer extends in a second lateral direction, the first lateral direction being perpendicular to the second lateral direction.

3. The circuit of claim 1, wherein the driver circuit is configured to assert one or more of the first memory cells through a second interconnect structure formed on the first side of the substrate.

4. The circuit of claim 1, further comprising:
a plurality of second memory cells physically disposed in a third region on the first side of the substrate;
wherein the third region is placed opposite the second region from the first region.

5. The circuit of claim 1, wherein, with the supply voltage equal to VDD, the switch circuit includes one or more p-type transistors.

6. The circuit of claim 1, wherein, with the supply voltage equal to VSS, the switch circuit includes one or more n-type transistors.

7. The circuit of claim 1, further comprising:
a repeater circuit operatively coupled to the driver circuit and physically disposed in a fourth region adjacent to the first region;
wherein the repeater circuit is coupled to the driver circuit through the second interconnect layer formed on a second side of the substrate.

8. The circuit of claim 7, further comprising:
a plurality of third memory cells physically disposed in a fifth region on the first side of the substrate;
wherein the fifth region is placed opposite the first region from the fourth region, and the second interconnect layer extends through the plurality of third memory cells.

9. A circuit, comprising:
a driver circuit physically disposed in a first region on a first side of a substrate, between a plurality of first memory cells and a plurality of second memory cells; and
a switch circuit configured to selectively couple a supply voltage to the driver circuit as an operational voltage;
wherein an operational voltage is carried through at least a first interconnect structure, a second interconnect structure, and a third interconnect structure, and wherein the first interconnect structure is formed on the first side of the substrate, the second interconnect structure is formed on a second, opposite side of the substrate, and the third interconnect structure is formed on a second side of the substrate.

10. The circuit of claim 9, wherein the second interconnect structure extends in a first lateral direction and the third interconnect structure extends in a second lateral direction, the first lateral direction being perpendicular to the second lateral direction.

11. The circuit of claim 9, wherein, with the supply voltage equal to VDD, the switch circuit includes one or more p-type transistors.

12. The circuit of claim 9, wherein, with the supply voltage equal to VSS, the switch circuit includes one or more n-type transistors.

13. The circuit of claim 9, further comprising:
a repeater circuit operatively coupled to the driver circuit and physically disposed between the plurality of first memory cells and a plurality of third memory cells;
wherein the repeater circuit is coupled to the driver circuit through the second side of the substrate.

14. The circuit of claim 13, wherein the repeater circuit includes a fifth interconnect structure on the second side of the substrate.

15. The circuit of claim 13, wherein, with the supply voltage equal to VDD, the repeater circuit includes one or more p-type transistors.

16. A method, comprising:
forming one or more first transistors in a plurality of first memory cells in a first region on a first side of a substrate, a driver circuit in a second region on the first side of the substrate, and a switch circuit on the first side of the substrate;
forming one or more first interconnect structures on the first side to operatively couple the plurality of first memory cells to the driver circuit and allow the switch circuit to selectively couple a supply voltage to the driver circuit as an operational voltage;
forming a via structure configured to electrically connect the first side of the substrate to a second, opposite side of the substrate;
forming a first interconnect layer on a second side of the substrate; and
forming a second interconnect layer on the second side of the substrate,
wherein the operational voltage is carried by the one or more first interconnect structures, and at least one of the first interconnect layer and the second interconnect layer.

17. The method of claim 16, wherein the first interconnect layer extends in a first lateral direction and the second interconnect layer extends in a second lateral direction, the first lateral direction being perpendicular to the second lateral direction.

18. The method of claim 16, further comprising:
forming one or more second transistors in a plurality of second memory cells in a third region on the first side of the substrate;
wherein the third region is placed opposite the second region from the first region.

19. The method of claim 16, further comprising:
forming one or more p-type transistors in the switch circuit to provide the supply voltage equal to VDD, or
forming one or more n-type transistors in the switch circuit to provide the supply voltage equal to VSS.

20. The method of claim 16, further comprising:
forming a repeater circuit, operatively coupled to the driver circuit, in a fourth region adjacent to the first region;
wherein the repeater circuit is coupled to the driver circuit through the second interconnect layer formed on the second side of the substrate.
